(19) United States
(12) Patent Application Publication
(10) Pub. No.: US 2013/0327563 A1
(43) Pub. Date: Dec. 12, 2013

(54) PRINTED WIRING BOARD AND SOLDERING METHOD

(71) Applicant: FUJITSU LIMITED, Kawasaki-shi (JP)

(72) Inventor: Takahiro KITAGAWA, Kawasaki (JP)

(21) Appl. No.: 13/908,865

(22) Filed: Jun. 3, 2013

(30) Foreign Application Priority Data
Jun. 7, 2012 (JP) 2012-130136

(51) Int. Cl. H05K 13/04; H05K 1/18

(52) U.S. Cl. CPC H05K 13/04; H05K 1/181
USPC 174/257; 228/180.1

(57) ABSTRACT

There is provided a printed wiring board which includes a substrate, and a soldering portion disposed on the substrate, an electronic component being to be soldered to the solder portion. The soldering portion includes a first conductor to which a solder paste is applied, and a plurality of second conductors extends in a direction away from the first conductor, where the plurality of second conductors extend parallel to each other and linearly.

### CROSS-REFERENCE TO RELATED APPLICATION

This application is based upon and claims the benefit of priority of the prior Japanese Patent Application No. 2012-130136, filed on Jun. 7, 2012, the entire contents of which are incorporated herein by reference.

### FIELD

The embodiments discussed herein are related to printed wiring boards and soldering methods.

### BACKGROUND

Electronic components for mounting on printed wiring boards include insertion-mount devices (IMDs) and surface-mount devices (SMDs). An example of a known process for mounting an IMD or SMD on a printed wiring board is reflow soldering. In reflow soldering, an electronic component is placed on a board coated or printed with a solder paste in advance, and a terminal of the electronic component is soldered to a predetermined position of the board by heating the entire board using a heater, called a reflow oven, to melt the solder. The temperature in the reflow oven may be controlled to uniformly melt the solder on the printed wiring board.

Examples of the related art are disclosed in Japanese Laid-open Patent Publication Nos. 2000-91737 and 11-204897.

### SUMMARY

According to an aspect of the invention, a printed wiring board includes a substrate, and a soldering portion disposed on the substrate, an electronic component being to be soldered to the solder portion. The soldering portion includes a first conductor, a solder paste being applied to the first conductor, and a plurality of second conductors extending in a direction away from the first conductor, the plurality of second conductors extending parallel to each other and linearly.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view of a printed wiring board according to a first example of a first embodiment;

FIG. 2 is a top view of the printed wiring board at and around a soldering portion;

FIG. 3 schematically illustrates a cross-section taken along line III-III in FIG. 2;

FIG. 4 schematically illustrates a cross-section taken along line IV-IV in FIG. 2;

FIG. 5 is a first view illustrating a soldering method for mounting a connector on the soldering portion of the printed wiring board;

FIG. 6 is a second view illustrating the soldering method for mounting a connector on the soldering portion of the printed wiring board;

FIG. 7A is a first view illustrating the behavior of solder paste during reflow treatment;

FIG. 7B is a second view illustrating the behavior of solder paste during reflow treatment;

FIG. 7C is a third view illustrating the behavior of solder paste during reflow treatment;

FIG. 8 schematically illustrates solder and flux that have spread over the soldering portion upon completion of reflow treatment;

FIG. 9 illustrates a soldering portion according to a first modification of the first embodiment;

FIG. 10 is a top view of a printed wiring board according to a second example of the first embodiment at and around a soldering portion;

FIG. 11 schematically illustrates a cross-section taken along line XI-XI in FIG. 10;

FIG. 12 schematically illustrates a cross-section taken along line XII-XII in FIG. 10;

FIG. 13A is a first view illustrating the behavior of solder paste during reflow treatment;

FIG. 13B is a second view illustrating the behavior of solder paste during reflow treatment;

FIG. 13C is a third view illustrating the behavior of solder paste during reflow treatment;

FIG. 14 schematically illustrates solder and flux that have spread over the soldering portion upon completion of reflow treatment;

FIG. 15 illustrates a soldering portion according to a second modification of the first embodiment;

FIG. 16 is a top view of a printed wiring board according to a third example of the first embodiment at and around a soldering portion;

FIG. 17 schematically illustrates a cross-section taken along line XVII-XVII in FIG. 16;

FIG. 18 schematically illustrates a cross-section taken along line XVIII-XVIII in FIG. 16;

FIG. 19A is a first view illustrating the behavior of solder paste during reflow treatment;

FIG. 19B is a second view illustrating the behavior of solder paste during reflow treatment;

FIG. 20 schematically illustrates solder and flux that have spread over the soldering portion upon completion of reflow treatment;

FIG. 21 illustrates a soldering portion according to a third modification of the first embodiment;

FIG. 22A illustrates the relationship between soldering portions to which a connector is soldered and a general-purpose soldering portion on the printed wiring board according to the first example of the first embodiment;

FIG. 22B illustrates the relationship between soldering portions to which a connector is soldered and a general-purpose soldering portion on the printed wiring board according to the second example of the first embodiment;

FIG. 22C illustrates the relationship between soldering portions to which a connector is soldered and a general-purpose soldering portion on the printed wiring board according to the third example of the first embodiment; and

FIG. 23 is a top view of a printed wiring board according to a second embodiment at and around a soldering portion.

### DESCRIPTION OF EMBODIMENTS

Preliminary Consideration

In reflow soldering, solder and flux spread easily because the solder on the board is uniformly heated. This may result in excessive wetting-up of the molten solder and flux along the electronic component during reflow heating, and the solder and flux may enter the interior of the electronic component. For example, when a connector, which is an example of an electronic component, is mounted, solder and flux may wet up to a plug-receiving portion of the connector. As a result, when a plug is connected to the connector, solidified solder or flux residue may interfere with the plug and thus make it difficult to insert the plug into the connector.

For reflow soldering of an IMD, a lead terminal of the IMD is inserted into a through-hole filled with a solder paste in a board. During reflow heating, solder and flux wet up easily along the lead terminal of the IMD, which may cause the problem described above. One approach to inhibiting excessive wetting-up of the solder and flux is to reduce the amount of solder printed on the board. This, however, may result in insufficient filling of the through-hole with the solder. Conventionally, an electronic component is manually soldered to a board. Manual soldering is effective in inhibiting excessive wetting-up of solder and flux because the board is locally heated, for example, from the backside. Unfortunately, manual soldering often involves increased workload.

In light of the foregoing, it is desirable to provide a technique for inhibiting excessive wetting-up of solder and flux during reflow soldering when mounting an electronic component on a printed wiring board.

Printed wiring boards and soldering methods for mounting electronic components on printed wiring boards according to embodiments will now be described in detail by way of example with reference to the drawings.

### First Embodiment

### Printed Wiring Board

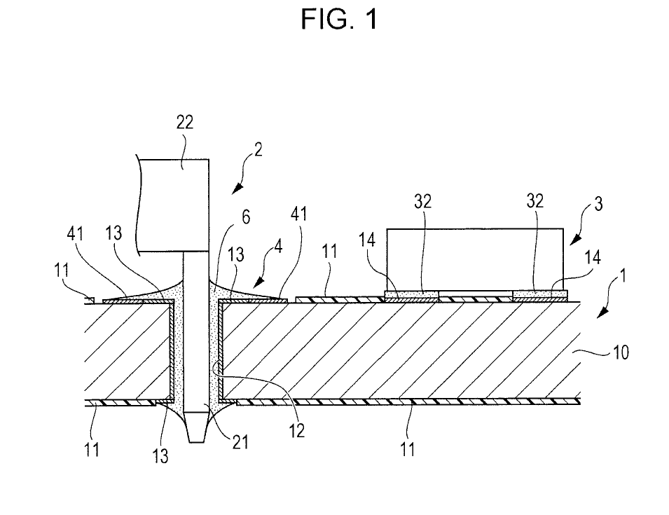

FIG. 1 is a sectional view of a printed wiring board 1 according to a first embodiment. The printed wiring board 1 includes a flat substrate 10 on which are disposed a conductive layer forming circuits such as signal circuits and power supply circuits and a solder resist 11 covering the conductive layer. The printed wiring board 1 has a connector 2 and a chip component 3 mounted thereon. The solder resist 11 may be, for example, a thermosetting resin such as epoxy resin. The solder resist 11 may be formed by, for example, a printing process such as screen printing.

The connector 2 is an IMD including a lead terminal 21 and a component body 22 and is soldered to the printed wiring board 1 with a solder member 6. The chip component 3 is, for example, an SMD including two terminals and is soldered to the printed wiring board 1 with solder members 32. The connector 2 is an example of an IMD, and other electronic components may instead be mounted on the printed wiring board 1. The chip component 3 is an example of an SMD, and other electronic components may instead be mounted on the printed wiring board 1.

The printed wiring board 1 has a through-hole 12 extending through the printed wiring board 1 across the thickness thereof. Lands 13 are formed in an exposed manner around the through-hole 12 on the surfaces of the printed wiring board 1. The lands 13 are footprints for applying a solder paste to solder the connector 2 to the printed wiring board 1 and are formed on the top and bottom surfaces of the printed wiring board 1. Also, pads 14 are formed in an exposed manner on the top surface of the printed wiring board 1. The pads 14 are footprints for soldering the chip component 3 to the printed wiring board 1.

The connector 2 and the chip component 3 are mounted on the printed wiring board 1 by reflow soldering. For mounting of the connector 2 and the chip component 3, a stencil mask (not illustrated) having a pattern opening is placed on the printed wiring board 1, and a solder paste is applied using, for example, a printing apparatus. The opening of the stencil mask is formed such that the tops of the lands 13 and the pads 14 are exposed when the mask is placed on the printed wiring board 1. The solder paste supplied from the printing apparatus is applied (transferred) to the lands 13 and the pads 14. The solder paste supplied from the printing apparatus also fills the through-hole 12.

The connector 2 and the chip component 3 are then mounted at predetermined positions of the printed wiring board 1, and the entire printed wiring board 1 is heated in a reflow oven (not illustrated). The solder paste supplied to the printed wiring board 1 melts and then solidifies, thus bonding the connector 2 and the chip component 3 to the lands 13 and the pads 14, respectively. The solder paste is a viscous material containing solder powder and flux.

The reflow oven incorporates, for example, a far-infrared heater or hot-air heater. The temperature in the reflow oven is controlled to uniformly heat the solder paste on the printed wiring board 1. For reflow soldering of an electronic component to a printed wiring board in the related art, the solder (solder powder) and flux contained in the solder paste may excessively wet up during reflow heating. In particular, for the connector 2, which is mounted by inserting the lead terminal 21 into the through-hole 12, solder and flux may flow along the lead terminal 21 and enter the interior of the component body 22 during reflow soldering. This may result in, for example, deposition of flux residue or solder on a plug-receiving portion (not illustrated) of the connector 2. When the user of the printed wiring board 1 connects a plug to such a connector 2, the solder or flux residue deposited on the plug-receiving portion of the connector 2 may interfere with the plug and thus make it difficult to connect the plug to the connector 2.

According to this embodiment, the printed wiring board 1 addresses the above problem by the use of a soldering portion 4 having a distinctive structure to which the connector 2, which is an IMD, is soldered. The soldering portion 4 of the printed wiring board 1 will now be described in detail with reference to the drawings.

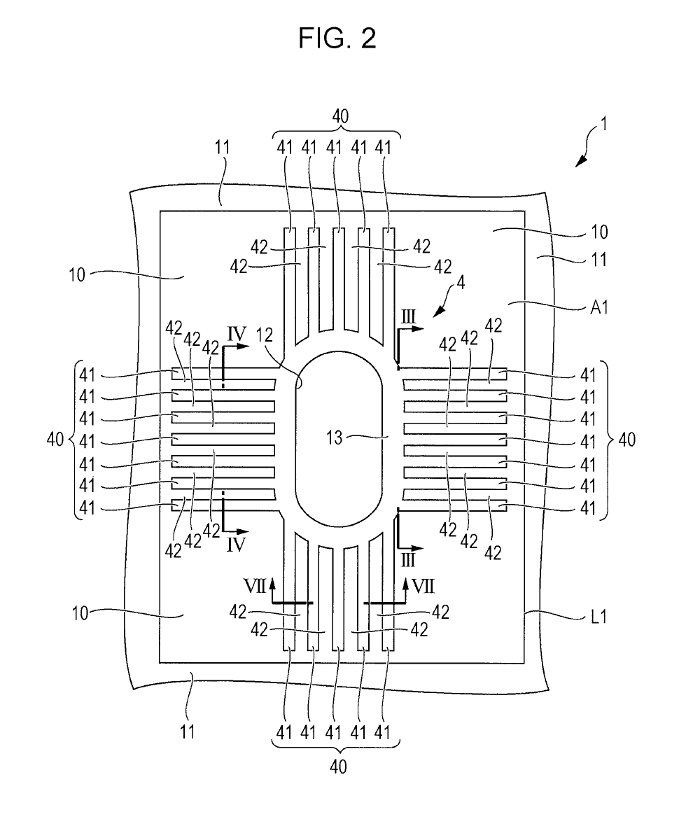

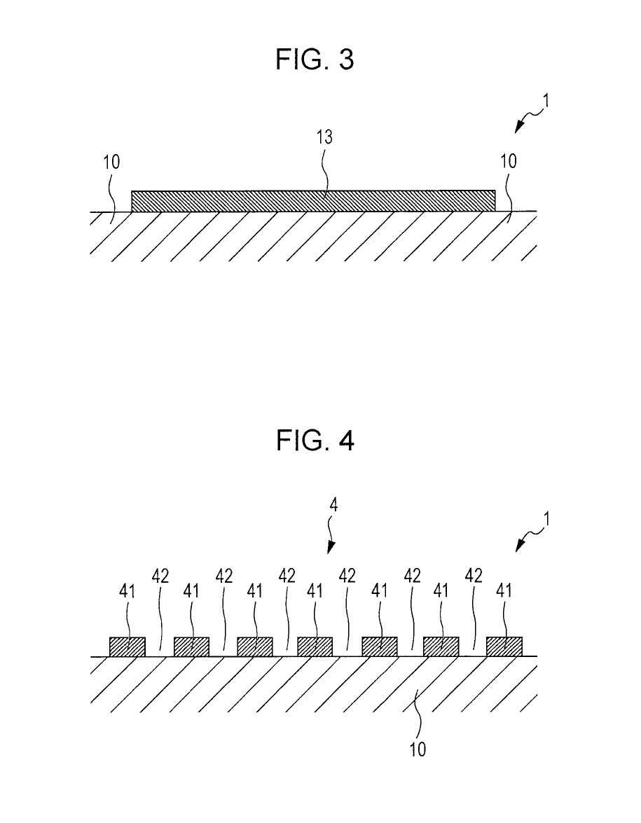

FIG. 2 is a top view of the printed wiring board 1 at and around the soldering portion 4. FIG. 2 illustrates the top surface of the printed wiring board 1 before the connector 2 is mounted thereon. In this embodiment, the connector 2 and the chip component 3 are mounted on the top surface of the printed wiring board 1. FIGS. 3 and 4 illustrate the cross-sectional structure of the printed wiring board 1 at and around the soldering portion 4. FIG. 3 schematically illustrates a cross-section taken along line III-III in FIG. 2. FIG. 4 schematically illustrates a cross-section taken along line IV-IV in FIG. 2.

The solder resist 11 has a rectangular cutout around the soldering portion 4 on the top surface of the printed wiring board 1. In the example illustrated in FIG. 2, the solder resist 11 has a cutout region A1 in a rectangular area L1. In this embodiment, the soldering portion 4 is formed of a patterned conductive layer on the substrate 10 and includes a land 13 and a plurality of linear conductors 41. The surface of the substrate 10 is exposed as the outermost layer (topmost layer) in the portion of the cutout region A1 where the conductive layer for the soldering portion 4 is not formed.

The soldering portion 4 includes the land 13, which surrounds the through-hole 12, and the linear conductors 41, which extend linearly outward from the lands 13. The linear conductors 41 are exposed on the surface of the printed wiring board 1. The land 13 is a conductor for soldering the connector 2 to the printed wiring board 1. To mount the connector 2, a solder paste is applied (transferred) to the land 13. The land 13 is an example of a first conductor. The linear conductors 41 are an example of a second conductor. The land 13 and the linear conductors 41 may be formed in various patterns using various materials. In this embodiment, the land 13 and the linear conductors 41 are formed of copper foil.

In this embodiment, the soldering portion 4 includes a plurality of linear conductor groups 40, each including a plurality of linear conductors 41 extending in the same direction. In the example illustrated in FIG. 2, four linear conductor groups 40 extend from the land 13 in different directions in the plane of the printed wiring board 1. The linear conductors 41 in each linear conductor group 40 extend from the land 13 outward in the plane of the printed wiring board 1 and are arranged parallel to each other at regular intervals. Each linear conductor group 40 may include at least two linear conductors 41 and is not limited to any particular number of linear conductors 41. Although the soldering portion 4 includes four linear conductor groups 40 in the example illustrated in FIG. 2, the soldering portion 4 is not limited to any particular number of linear conductor groups 40 and may include one or more linear conductor groups 40. In this embodiment, the soldering portion 4 is smooth, with no step between the surface of the land 13 and the surfaces of the linear conductors 41.

The printed wiring board 1 has grooves 42 on the surface thereof, each formed by a pair of the linear conductors 41 parallel and adjacent to each other and a surface of the substrate 10 between the pair of the linear conductors 41 (see FIG. 4). The groove may be a channel or gutter. As illustrated in FIG. 4, the bottoms of the grooves 42 are formed by the surface of the substrate 10. The width of each linear conductor 41 is equal to each other (in the direction perpendicular to the longitudinal direction). Accordingly, the width of the grooves 42 is uniform in the longitudinal direction of the linear conductors 41.

Soldering Method

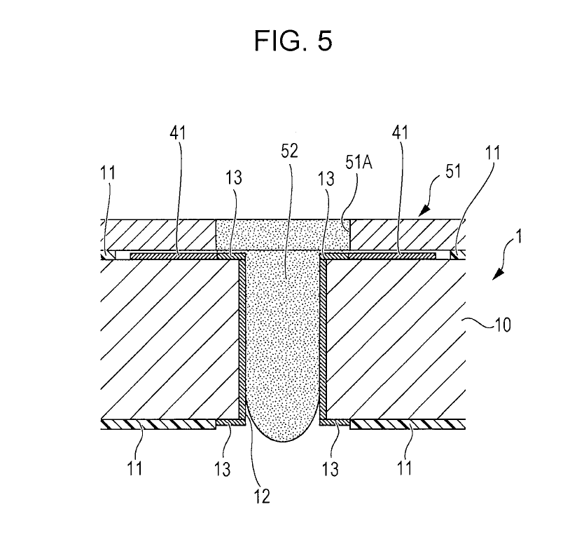

Next, a soldering method for mounting the connector 2 on the soldering portion 4 of the printed wiring board 1 will be described. Referring first to FIG. 5, a stencil mask 51 is placed on the top surface of the printed wiring board 1, and a solder paste 52 is printed on the top surface of the printed wiring board 1 using a printing apparatus (not illustrated). The stencil mask 51 is a mask having openings 51A formed in the regions corresponding to the land 13, the through-hole 12, and the pads 14 when placed on the top surface of the printed wiring board 1. The printing apparatus includes, for example, a squeegee. With the squeegee, the printing apparatus supplies (transfers or applies) the solder paste 52 to the openings 51A of the stencil mask 51. Thus, the solder paste 52 is supplied from the top side of the printed wiring board 1 to the interior of the through-hole 12 and the surface of the land 13. Although the pads 14 are not illustrated in FIG. 5, the solder paste 52 supplied from the printing apparatus is also transferred to the surfaces of the pads 14 through the openings 51A of the stencil mask 51.

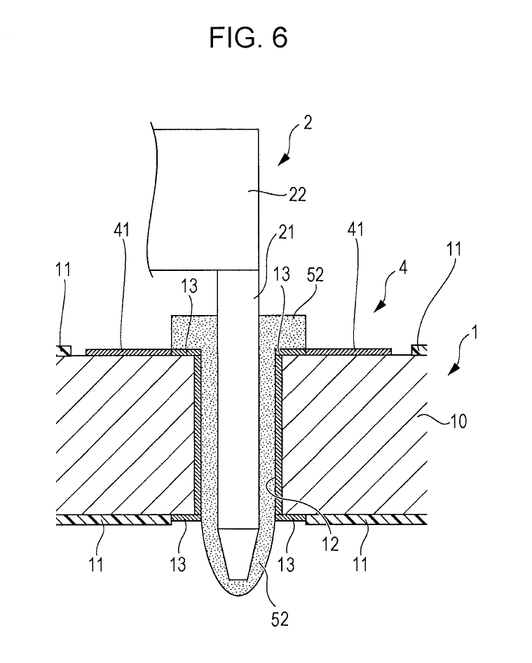

Referring now to FIG. 6, the lead terminal 21 of the connector 2 is inserted from the top side of the printed wiring board 1 into the through-hole 12. After the connector 2 is mounted on the top surface of the printed wiring board 1, reflow treatment (reflow step) is performed. In reflow treatment, the printed wiring board 1 in the state illustrated in FIG. 6 is heated in a reflow oven. During reflow treatment, the solder contained in the solder paste 52 melts and aggregates. Thus, the solder filling the entire through-hole 12 bonds the lead terminal 21 of the connector 2 to the plating in the through-hole 12. As a result, the connector 2 is mechanically and electrically connected to the printed wiring board 1.

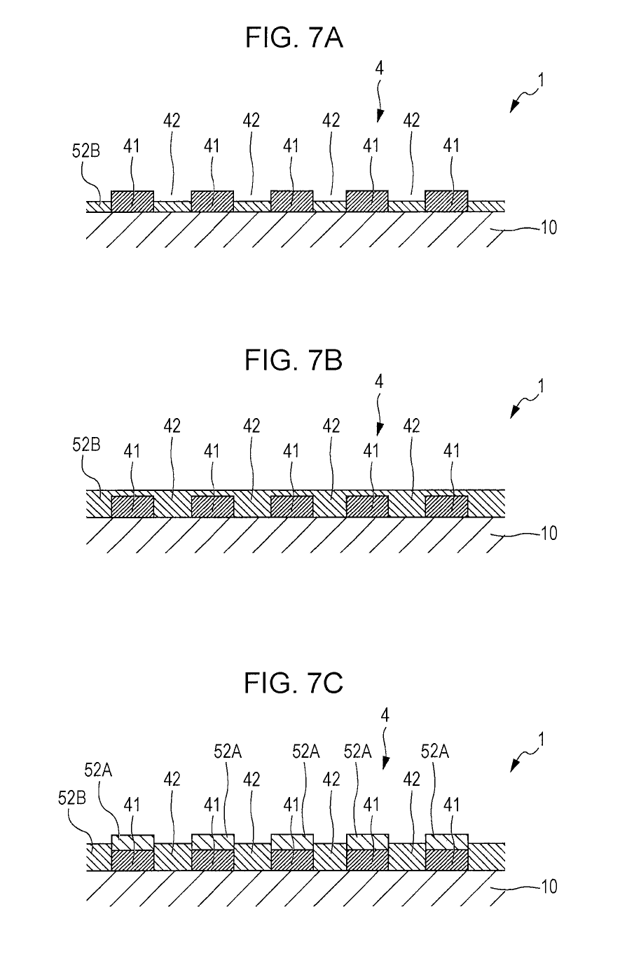

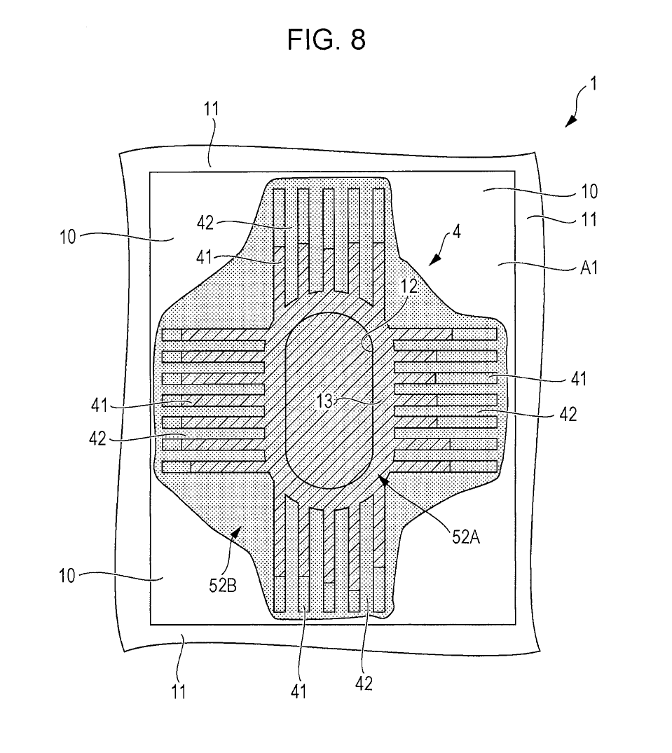

Next, the behavior of a solder 52A and a flux 52B contained in the solder paste 52 during reflow treatment will be described. In the reflow step of the method for soldering the connector 2 according to this embodiment, a portion of the molten solder paste 52 flows from the land 13 (first conductor) to the linear conductors 41 (second conductors). FIGS. 7A to 7C illustrate the behavior of the solder paste 52 during reflow treatment. FIGS. 7A to 7C schematically illustrate a cross-section taken along line VII-VII in FIG. 2. FIG. 8 schematically illustrates the solder 52A and the flux 52B that have spread over the soldering portion 4 upon completion of reflow treatment. In FIG. 8, the hatched region illustrates the coverage of the solder 52A, and the dotted region illustrates the coverage of the flux 52B.

When reflow treatment is started, the flux 52B contained in the solder paste 52 transferred to the land 13 melts first. The molten flux 52B flows from the land 13 into the grooves 42. The groove may be a channel or gutter. The grooves 42, which are elongated passages between pairs of the linear conductors 41 parallel and adjacent to each other, attract the molten flux 52B by capillary force. As a result, as illustrated in FIG. 7A, the molten flux 52B flows from the land 13 into the grooves 42 and flows through the grooves 42 toward the leading ends thereof.

The width of the grooves 42 is uniform in the longitudinal direction of the linear conductors 41. This provides a stable capillary force for transferring the flux 52B to the leading ends of the grooves 42 irrespective of the position along the length of the grooves 42. As a result, the molten flux 52B may be transferred to a position farther away from the land 13 along the grooves 42. The leading ends of the grooves 42 are ends opposite base ends adjoining the land 13 and correspond to the leading ends of the linear conductors 41.

As the level of the flux 52B flowing through the grooves 42 rises gradually in the reflow step, the flux 52B spills from the grooves 42. As illustrated in FIG. 7B, the flux 52B spilling from the grooves 42 flows across the surfaces of the linear conductors 41 toward the leading ends thereof while wetting the surfaces of the linear conductors 41. Thus, as illustrated in FIG. 8, the molten flux 52B may flow along the grooves 42 and the surfaces of the linear conductors 41 to spread in the plane of the printed wiring board 1 in the reflow step.

As illustrated in FIG. 7C, the solder 52A, which melts after the flux 52B melts, flows from the land 13 to the linear conductors 41, which are more wettable. The linear shape of the linear conductors 41 allows them to attract the solder 52A on the land 13 by capillary force. This promotes the flow of the solder 52A from the land 13 to the linear conductors 41. In addition, the flux 52B has already been supplied to the surfaces of the linear conductors 41. Because the flux 52B has wetted the surfaces of the linear conductors 41, the solder 52A exhibits decreased surface tension. This increases the flowability of the solder 52A to facilitate the flow of the solder 52A across the surfaces of the linear conductors 41 toward the leading ends thereof. Thus, as illustrated in FIG. 8, the solder 52A applied to the land 13 may flow along the linear conductors 41 to spread in the plane of the printed wiring board 1. The coverages of the solder 52A and the flux 52B in FIG. 8 are illustrative only.

With the linear conductors 41 extending outward from the land 13, as described above, the soldering portion 4 of the printed wiring board 1 provides the following advantageous effects. Specifically, when the solder paste 52 transferred to the land 13 melts, the soldering portion 4 allows a portion of the flux 52B and the solder 52A to spread from the land 13 outward in the plane of the printed wiring board 1. This inhibits excessive wetting-up of the flux 52B and the solder 52A along the lead terminal 21 during reflow treatment so that the solder 52A and the flux 52B do not enter the interior of the connector 2.

In this embodiment, the flux 52B and the solder 52A flow along the linear conductors 41 of the soldering portion 4. The direction in which the linear conductors 41 (linear conductor groups 40) extend may be set in advance to control the direction in which the flux 52B and the solder 52A spread during reflow treatment.

The amount of flux 52B and solder 52A wetting up along the connector 2 during reflow treatment depends on various parameters, including the number (total number) of linear conductors 41 of the soldering portion 4, the length of the linear conductors 41, and the width of the grooves 42. Such parameters may be adjusted to control the amount of flux 52B and solder 52A wetting up. For example, the amount of flux 52B and solder 52A wetting up decreases as more linear conductors 41 are provided, the linear conductors 41 become longer, and the grooves 42 become narrower. Thus, the height to which the flux 52B and the solder 52A wet up may be reduced.

The printed wiring board 1 according to this embodiment may be used without manual soldering. This allows inhibition of excessive wetting-up of the flux 52B and the solder 52A during the soldering of the lead terminal 21 without increased workload. In addition, the electronic component may be used without special treatment for inhibiting wetting-up of the solder 52A, such as forming a solder dam or nickel barrier on the lead terminal 21 of the connector 2. This ensures versatility of the printed wiring board 1 and does not involve increased costs of manufacturing the electronic component. Thus, the printed wiring board 1 according to this embodiment may inhibit excessive wetting-up of solder during the soldering of an electronic component without disadvantages such as increased workload, decreased versatility, and increased manufacturing costs.

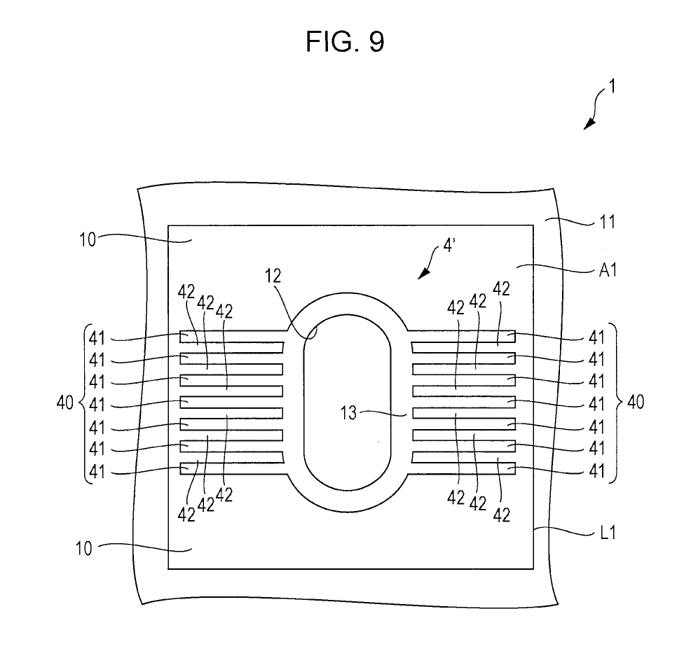

Various modifications of the soldering portion 4 according to this embodiment are possible. The printed wiring board 1 illustrated in FIGS. 1 to 8 is referred to as a first example. FIG. 9 illustrates a soldering portion 4′ according to a first modification, which is a modification of the first example. The soldering portion 4′ according to the first modification differs from the soldering portion 4 according to the first example in the number of linear conductor groups 40. The soldering portion 4′ includes two linear conductor groups 40 extending from the land 13 in different directions. For example, in some cases, the printed wiring board 1 has a limited space for the linear conductor groups 40 because various electronic components, including the connector 2 and the chip component 3, are mounted on the printed wiring board 1. In such cases, the number and positions of the linear conductor groups 40 disposed around the land 13 may be changed depending on various conditions for the printed wiring board 1.

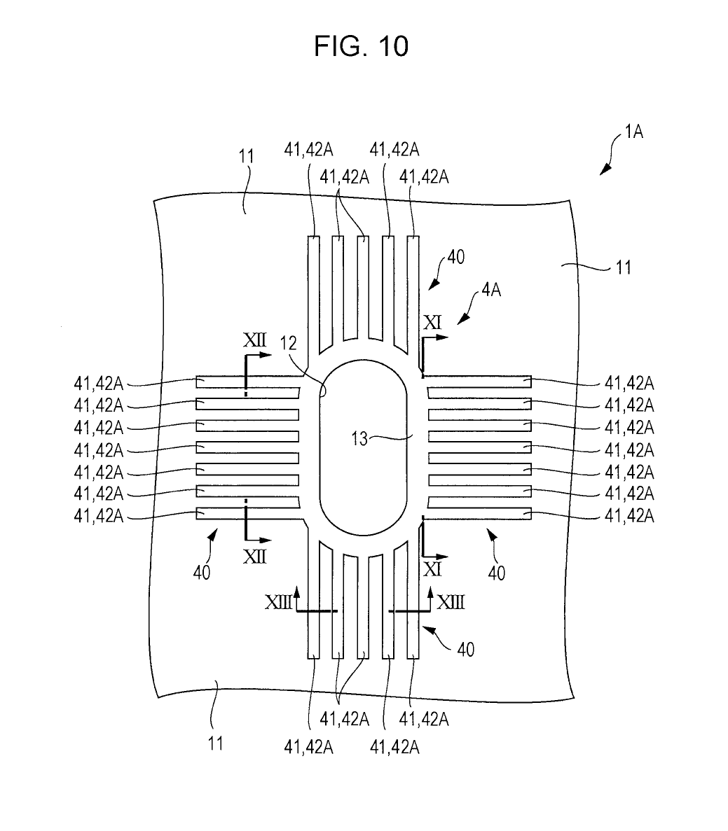

Next, a printed wiring board 1A according to a second example will be described with reference to FIGS. 10 to 14.

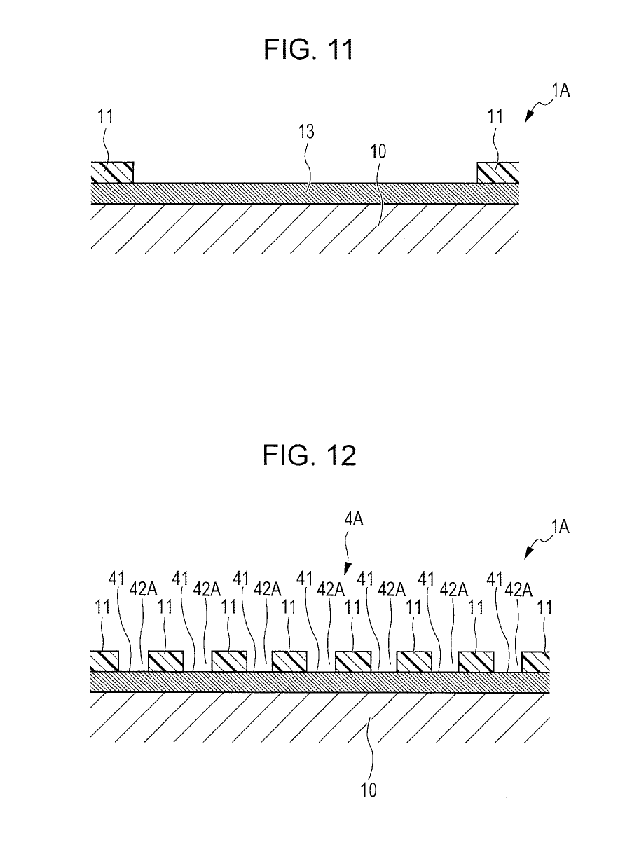

FIG. 10 is a top view of the printed wiring board 1A according to the second example at and around a soldering portion 4A. FIG. 10 illustrates the top surface of the printed wiring board 1A before the connector 2 is mounted thereon. The printed wiring board 1A according to the second example differs from the printed wiring board 1 according to the first example in the structure of the soldering portion 4A. FIGS. 11 and 12 illustrate the cross-sectional structure of the printed wiring board 1A at and around the soldering portion 4A. FIG. 11 schematically illustrates a cross-section taken along line XI-XI in FIG. 10. FIG. 12 schematically illustrates a cross-section taken along line XII-XII in FIG. 10.

The printed wiring board 1A includes a substrate 10 on which are disposed a copper foil serving as a conductive layer forming circuits such as power supply circuits and a solder resist 11 serving as a protective layer. In the second example, the solder resist 11 has an opening formed in the pattern corresponding to the land 13 and the linear conductors 41 of the soldering portion 4A, rather than a rectangular cutout, around the soldering portion 4A. A portion of the lower conductive layer is exposed in the opening of the solder resist 11. In the second example, the portion of the conductive layer exposed in the opening of the solder resist 11 forms the soldering portion 4A (land 13 and linear conductors 41).

In the soldering portion 4A, as in the soldering portion 4 according to the first example, the linear conductors 41 extend linearly outward from the land 13. The soldering portion 4A includes a plurality of linear conductor groups 40, each including a plurality of linear conductors 41 extending from the land 13 in the same direction. In the example illustrated in FIG. 10, four linear conductor groups 40 extend in different directions in the plane of the printed wiring board 1A. The linear conductors 41 in each linear conductor group 40 are arranged parallel to each other at regular intervals. In the second example, as illustrated in FIG. 12, grooves 42A are each formed by one of the linear conductors 41 and surfaces of the solder resist 11 on both sides of the linear conductor 41. As seen in FIG. 12, the bottoms of the grooves 42A are formed by the linear conductors 41.

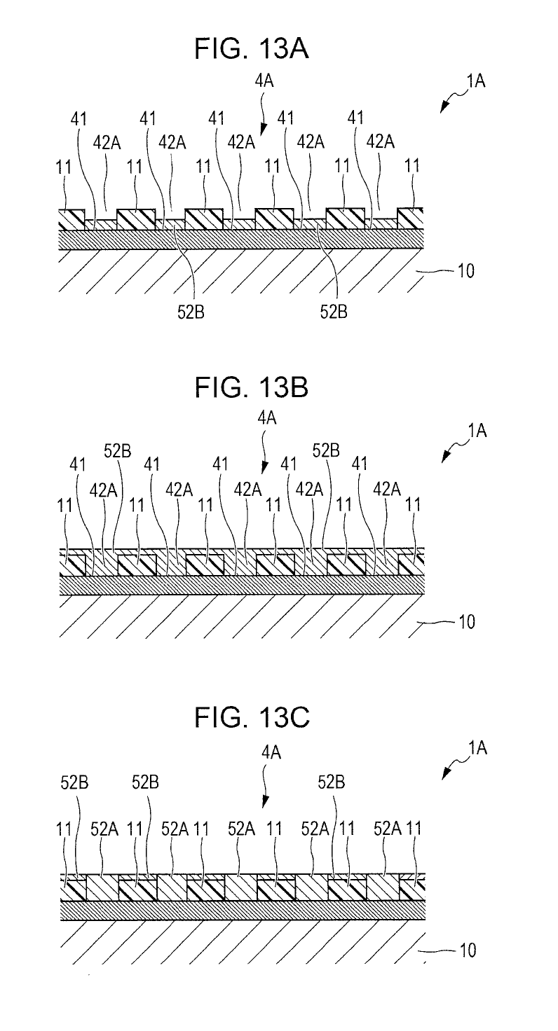

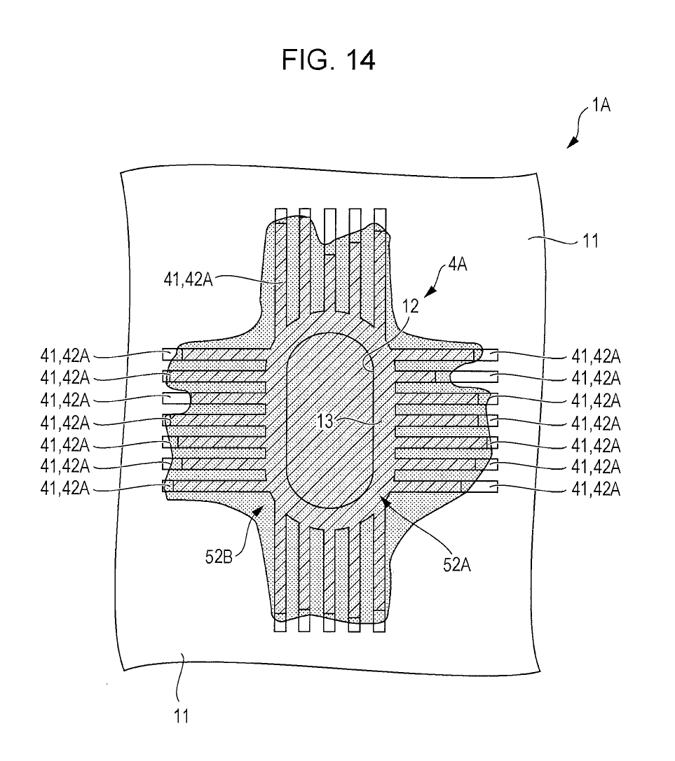

Next, the behavior of the solder 52A and the flux 52B contained in the solder paste 52 during reflow treatment in the second example will be described. FIGS. 13A to 13C illustrate the behavior of the solder paste 52 during reflow treatment. FIGS. 13A to 13C schematically illustrate a cross-section taken along line XIII-XIII in FIG. 10. FIG. 14 schematically illustrates the solder 52A and the flux 52B that have spread over the soldering portion 4A upon completion of reflow treatment. In FIG. 14, the hatched region illustrates the coverage of the solder 52A, and the dotted region illustrates the coverage of the flux 52B.

When reflow treatment is started, the flux 52B contained in the solder paste 52 transferred to the land 13 melts first. As illustrated in FIG. 13A, the molten flux 52B flows from the land 13 into the grooves 42A and flows through the grooves 42A toward the leading ends thereof. The bottoms of the grooves 42A are formed by the linear conductors 41, which are defined by the solder resist 11. During reflow heating, the grooves 42A attract the molten flux 52B by capillary force. This promotes the flow of the molten flux 52B from the land 13 into the grooves 42A. As the level of the flux 52B flowing through the grooves 42A rises gradually, the flux 52B spills from the grooves 42A. As illustrated in FIG. 13B, the flux 52B spilling from the grooves 42A flows across the surface of the solder resist 11. Thus, as illustrated in FIG. 14, the flux 52B may spread over a wide area in the plane of the printed wiring board 1.

As illustrated in FIG. 13C, the solder 52A, which melts after the flux 52B melts, flows from the land 13 into the grooves 42A formed by the linear conductors 41, which are more wettable. The linear shape of the linear conductors 41 allows the grooves 42A (linear conductors 41) to attract the solder 52A on the land 13 by capillary force. This promotes the flow of the solder 52A from the land 13 into the grooves 42A (linear conductors 41). In addition, the flux 52B has already been supplied to and wetted the grooves 42A (linear conductors 41). This increases the flowability of the solder 52A flowing into the grooves 42A (linear conductors 41) to facilitate the flow of the solder 52A toward the leading ends of the grooves 42A (linear conductors 41). As illustrated in FIG. 14, therefore, the solder 52A applied to the land 13 may spread along the linear conductors 41 over a wide area in the plane of the printed wiring board 1. Thus, the soldering portion 4A may inhibit excessive wetting-up of the flux 52B and the solder 52A during reflow treatment, as does the soldering portion 4 according to the first example.

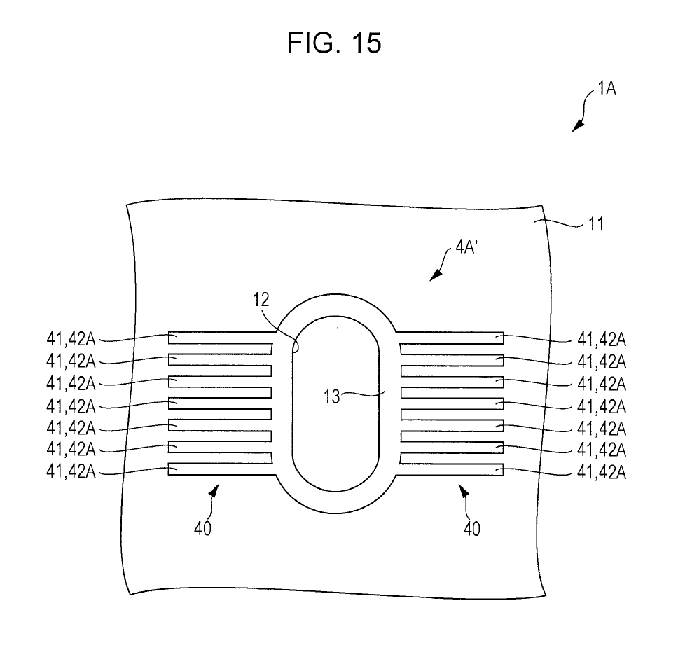

FIG. 15 illustrates a soldering portion 4A′ according to a second modification, which is a modification of the second example. The soldering portion 4A′ according to the second modification differs from the soldering portion 4A according to the second example in the number of linear conductor groups 40. The soldering portion 4A′ includes two linear conductor groups 40 extending from the land 13 in different directions. Thus, the soldering portion 4A is not limited to any particular number of linear conductor groups 40, but it may be changed.

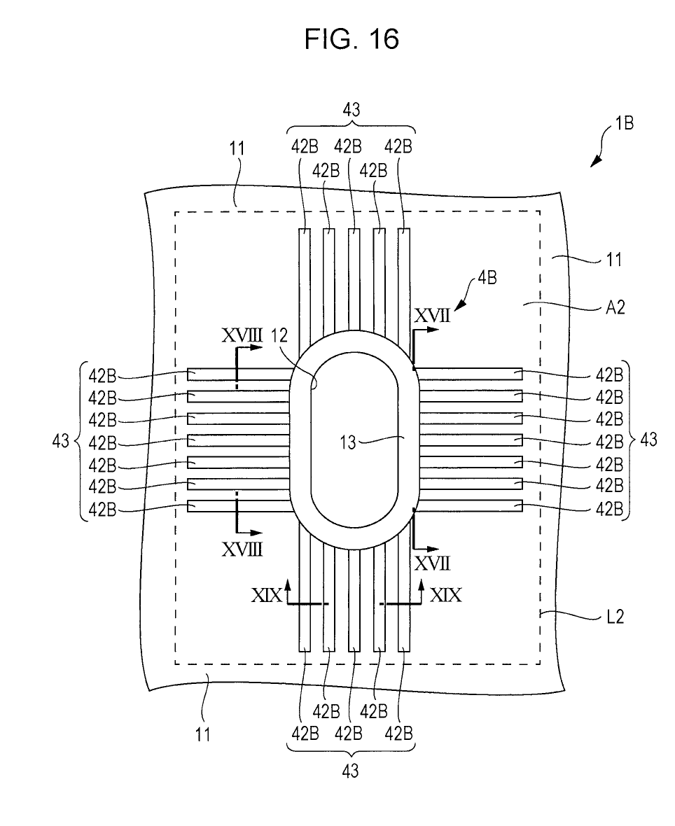

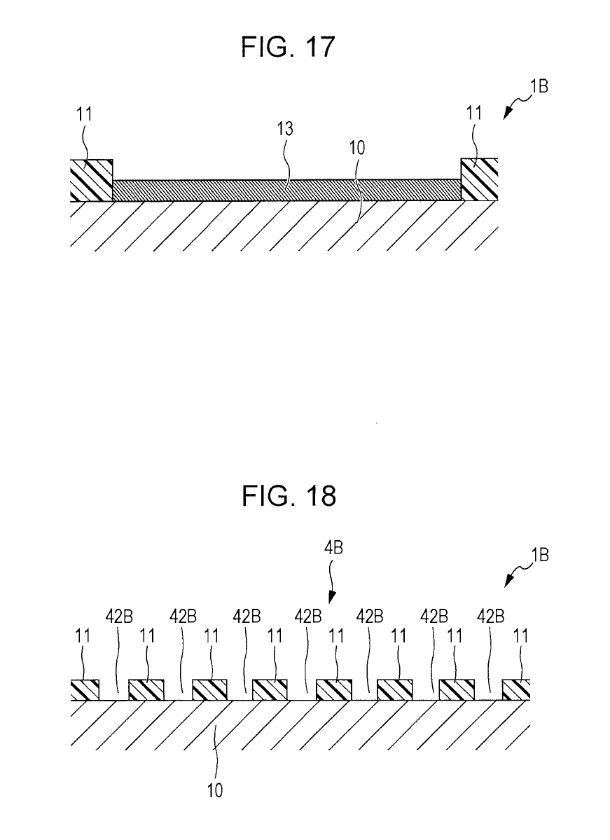

Next, a printed wiring board 1B according to a third example will be described with reference to FIGS. 16 to 20. The printed wiring board 1B includes a soldering portion 4B to which the connector 2 is soldered. FIG. 16 is a top view of the printed wiring board 1B according to the third example at and around the soldering portion 4B. FIG. 16 illustrates the top surface of the printed wiring board 1B before the connector 2 is mounted thereon. The printed wiring board 1B according to the third example differs from the printed wiring boards 1 and 1A according to the first and second examples in the structure of the soldering portion 4B. FIGS. 17 and 18 illustrate the cross-sectional structure of the printed wiring board 1B at and around the soldering portion 4B. FIG. 17 schematically illustrates a cross-section taken along line XVII-XVII in FIG. 16. FIG. 18 schematically illustrates a cross-section taken along line XVIII-XVIII in FIG. 16.

Whereas the soldering portions 4 and 4A according to the first and second examples control the amount of solder 52A and flux 52B wetting up during reflow treatment, the soldering portion 4B according to the third example controls the amount of flux 52B wetting up. The soldering portion 4B includes a land 13 and a plurality of grooves 42B extending from the land 13 outward in the plane of the printed wiring board 1B. A conductive layer disposed on the substrate 10 has a cutout in a region other than the region where the land 13 is formed around the soldering portion 4B on the top surface of the printed wiring board 1B. In the example illustrated in FIG. 16, the conductive layer has a cutout region A2 in a rectangular area L2 enclosed by the broken line.

In the cutout region A2, the solder resist 11 is directly formed on the substrate 10 in the region other than the region where the land 13 is formed. The solder resist 11 has an opening where the entire land 13 and portions of the substrate 10 are exposed. The opening of the solder resist 11 is located above the land 13 and the regions where the grooves 42B are formed and has the pattern corresponding to the soldering portion 4B. As a result, as illustrated in FIG. 16, the grooves 42B extending outward from the land 13 are formed in an exposed manner on the surface of the printed wiring board 1B. That is, the portions of the substrate 10 exposed in the opening of the solder resist 11 form the grooves 42B.

As illustrated in FIG. 16, the soldering portion 4B according to the third example includes a plurality of groove sets 43, each including a plurality of grooves 42B extending in the same direction. The grooves 42B in each groove set 43 are arranged parallel to each other at regular intervals. In the example illustrated in FIG. 16, four groove sets 43 extend in different directions in the plane of the printed wiring board 1B. Each groove set 43 includes at least two grooves 42B and is not limited to any particular number of grooves 42B. The width of each groove 42B in the groove sets 43 is equal to each other and is uniform in the longitudinal direction. As illustrated in FIG. 18, the bottoms of the grooves 42B are formed by the surface of the substrate 10.

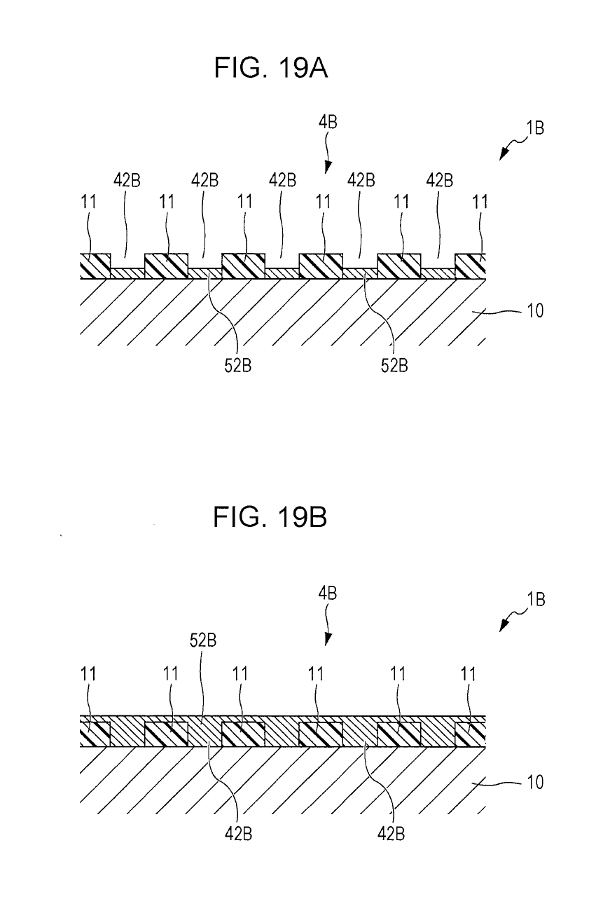

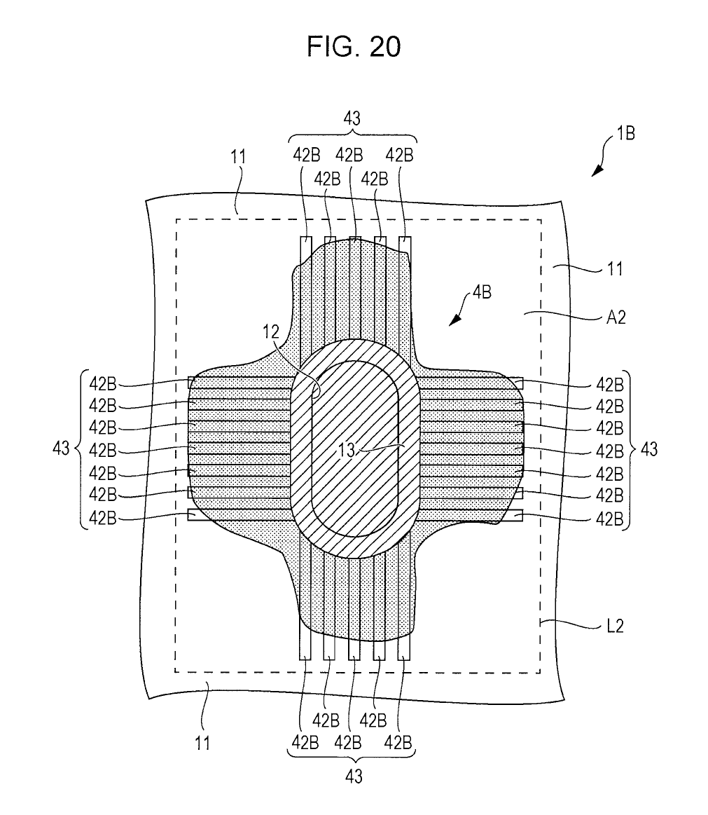

Next, the behavior of the flux 52B during reflow treatment in the third example will be described. FIGS. 19A and 19B illustrate the behavior of the flux 52B during reflow treatment. FIGS. 19A and 19B schematically illustrate a cross-section taken along line XIX-XIX in FIG. 16. FIG. 20 schematically illustrates the solder 52A and the flux 52B that have spread over the soldering portion 4B upon completion of reflow treatment. In FIG. 20, the hatched region illustrates the coverage of the solder 52A, and the dotted region illustrates the coverage of the flux 52B.

When reflow treatment is started, the flux 52B contained in the solder paste 52 transferred to the land 13 melts first. The grooves 42 then attract the molten flux 52B by capillary force. As a result, as illustrated in FIG. 19A, the molten flux 52B flows from the land 13 into the grooves 42B and flows through the grooves 42B toward the leading ends thereof. In this example, the grooves 42B in each groove set 43 are arranged parallel to each other and extend with uniform width. This provides a stable capillary force for transferring the flux 52B to the leading ends of the grooves 42B irrespective of the position along the length of the grooves 42B. As a result, the molten flux 52B may be transferred to a position farther away from the land 13 along the grooves 42B.

Thus, as illustrated in FIG. 20, the molten flux 52B may flow along the grooves 42B to spread over a wide area in the plane of the printed wiring board 1B. As the level of the flux 52B flowing through the grooves 42B rises gradually, the flux 52B spills from the grooves 42B. As illustrated in FIG. 19B, the flux 52B spilling from the grooves 42B flows across the surface of the solder resist 11.

In this example, the land 13 is surrounded by the grooves 42B formed by the surface of the substrate 10 and the solder resist 11 formed between the grooves 42B. The surface of the substrate 10 and the solder resist 11 are less wettable to the solder 52A than copper foil. During reflow treatment, therefore, most of the molten solder 52A remains on the land 13 without flowing into the grooves 42B. This allows only the flux 52B to be selectively spread in the plane of the printed wiring board 1B during reflow treatment. Thus, the soldering portion 4B according to the third example may selectively reduce the amount of flux 52B wetting up, rather than both of the solder 52A and the flux 52B contained in the solder paste 52, so that the flux 52B do not enter the interior of the connector 2.

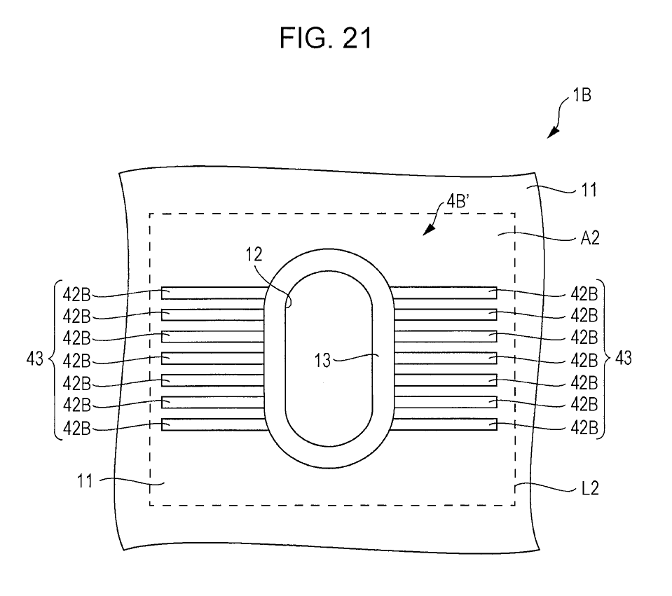

FIG. 21 illustrates a soldering portion 4B′ according to a third modification, which is a modification of the third example. The soldering portion 4B′ according to the third modification differs from the soldering portion 4B according to the third example in the number of groove sets 43. The soldering portion 4B′ includes two groove sets 43 extending from the land 13 in different directions. Thus, the soldering portion 4B is not limited to any particular number of groove sets 43, but it may be changed.

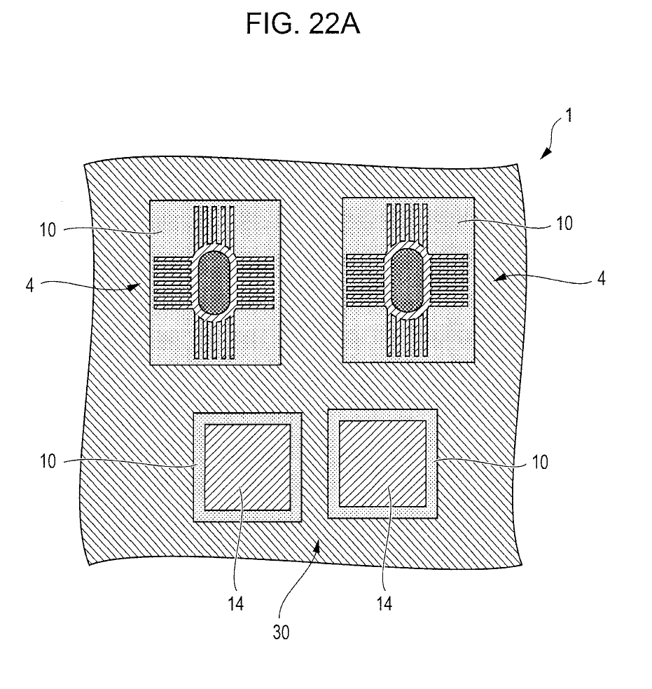

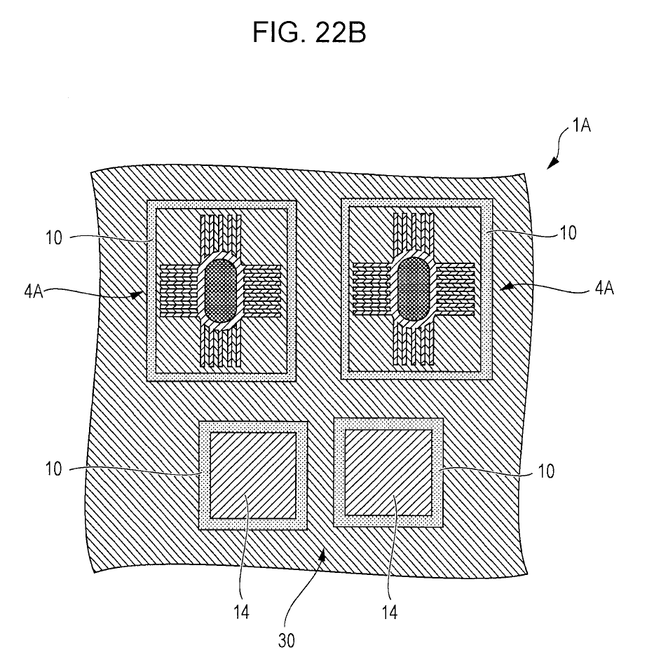

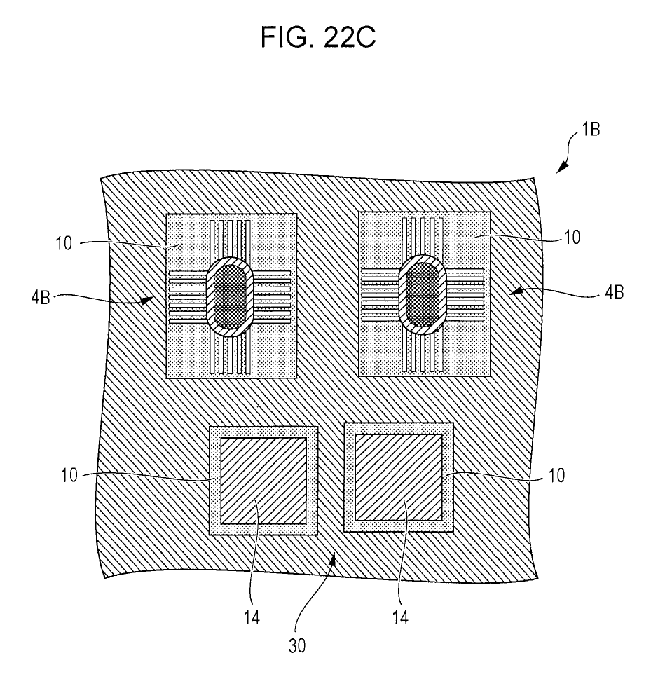

Next, the relationships between the soldering portions 4, 4A, and 4B to which the connector 2 is soldered and a soldering portion (hereinafter referred to as “general-purpose soldering portion”) 30 to which the chip component 3 is soldered on the printed wiring boards 1, 1A, and 1B according to the first, second, and third examples will be described. FIGS. 22A to 22C illustrate the relationships between the soldering portions 4, 4A, and 4B and the general-purpose soldering portion 30 on the printed wiring boards 1, 1A, and 1B according to the first, second, and third examples, respectively. The soldering portions 4, 4A, and 4B illustrated in FIGS. 22A to 22C are as described above, and no detailed description is given herein.

In FIGS. 22A to 22C, the hatched regions indicate the copper foil serving as the conductive layer on the substrate 10, and the dotted regions indicate cutouts in the copper foil. For illustration purposes, the solder resist 11 is not illustrated in FIGS. 22A to 22C. The general-purpose soldering portion 30 includes two pads 14, each of which is soldered to a terminal of the chip component 3 (see FIG. 1). The copper foil has cutouts around the pads 14 so that the connector 2 bonded to the soldering portion 4, 4A, or 4B does not short to the chip component 3.

### EXAMPLES

Next, the Examples will be described. The soldering portion 4 according to the first example in FIG. 2 and the soldering portion 4′ according to the first modification in FIG. 9 were tested for the effect of inhibiting wetting-up of solder during reflow treatment. The example for the soldering portion 4 is referred to as Example 1, and the example for the soldering portion 4′ is referred to as Example 2. Examples 1 and 2 were evaluated by comparing the heights to which solder wetted up in Examples 1 and 2 with that in the Comparative Example below. In the Comparative Example, the soldering portion had no linear conductors around the land. The land in the Comparative Example was similar to the land 13 in Examples 1 and 2. In Examples 1 and 2, the grooves 42 had a width of 0.12 mm, a spacing of 0.12 mm, and a length of 1.3 mm. The groove may be a channel or gutter. In Example 1, the soldering portion 4 included a total of 24 grooves 42 (see FIG. 2). In Example 2, the soldering portion 4′ included a total of 14 grooves 42 (see FIG. 9).

In this test, a solder paste was supplied to the land 13 of each of Examples 1 and 2 and the Comparative Example using the same stencil mask and printing apparatus, and reflow treatment was performed under the same conditions. After the reflow treatment, the height to which the solder wetted up was measured. Whereas the wetting height of the Comparative Example was about 1.23 mm, the wetting height of Example 2 was about 1.05 mm, and the wetting height of Example 1 was about 0.68 mm. This test demonstrated that the linear conductors 41 extending from the land 13 may effectively inhibit wetting-up of solder during reflow treatment.

### Second Embodiment

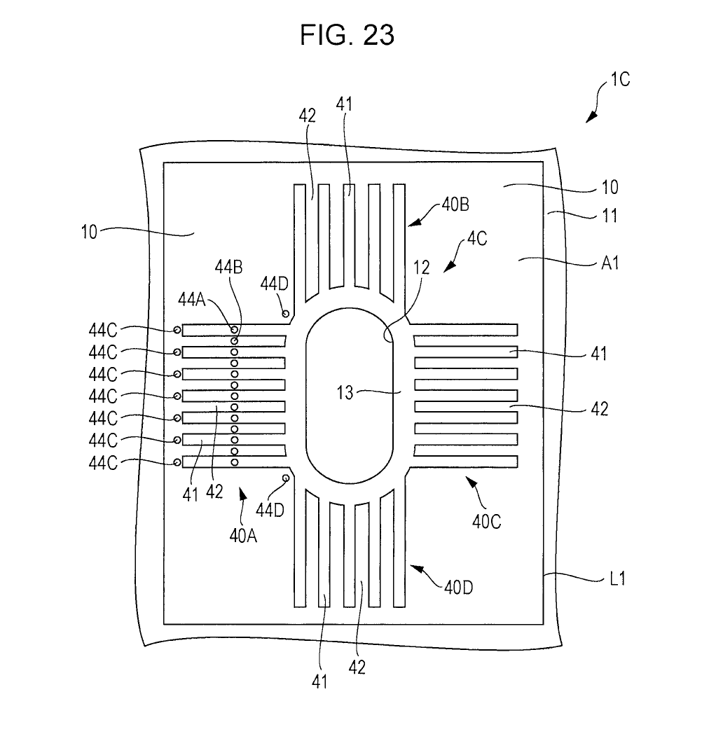

Next, a second embodiment will be described. FIG. 23 is a top view of a printed wiring board 1C according to the second embodiment at and around a soldering portion 4C. The printed wiring board 1C according to the second embodiment has recesses that are open upward. The recesses are formed in the surfaces of the linear conductors 41 of the soldering portion 4C, around the linear conductors 41, or both. Other features are roughly similar to those of the printed wiring board 1 according to the first example of the first embodiment. The description below will focus on the differences between the printed wiring board 1C and the printed wiring board 1.

As illustrated in FIG. 23, the soldering portion 4C of the printed wiring board 1C includes four linear conductor groups 40, which are respectively referred to as linear conductor groups 40A to 40D. The linear conductor group 40A has first to fourth recesses 44A to 44D formed in the surfaces of the linear conductors 41 and in the regions around the linear conductors 41. The first recesses 44A are formed in the surfaces of the linear conductors 41. The second recesses 44B are formed in the regions around the linear conductors 41, i.e., in the grooves 42. The groove may be a channel or gutter. Although the second recesses 44 illustrated in FIG. 23 are formed near the center of the grooves 42 in the longitudinal direction, they may be formed at any position of the grooves 42B in the longitudinal direction. The third recesses 44C are formed in the regions around the linear conductors 41, i.e., near the leading ends of the linear conductors 41. The fourth recesses 44D are formed in the regions around the linear conductor group 40, i.e., between the linear conductors 41 in the linear conductor group 40A and the linear conductors 41 in different linear conductor groups 40.

The size and shape of the recesses 44A to 44D, including the depth and horizontal cross-sectional area thereof, may be changed. The recesses 44A to 44D may be, for example, vias, through-holes, or non-through holes. The recesses 44A to 44D are an example of a hole that is open upward. Although the recesses 44A to 44D illustrated in this embodiment are depressions formed in the surface of the printed wiring board 1C, they may extend through the printed wiring board 1C.

Next, the function of the recesses 44A to 44D during reflow treatment will be described. During reflow treatment, the molten flux 52B flows through the grooves 42 and across the surfaces of the linear conductors 41, and the molten solder 52A flows across the linear conductors 41. Because the printed wiring board 1C has the recesses 44A to 44D formed in the surfaces of the linear conductors 41 and around the linear conductors 41, the molten flux 52B and solder 52A flow into the recesses 44A to 44D. The recesses 44A to 44D store the solder 52A and flux 52B flowing into the recesses 44A to 44D during reflow treatment. Thus, the printed wiring board 1C allows the molten solder 52A and flux 52B not only to be spread in the plane of the printed wiring board 1C during reflow treatment, but also to be distributed in the thickness direction, thereby inhibiting excessive wetting-up of the solder 52A and the flux 52B.

For example, the recesses 44A to 44D may be formed in the surfaces of the linear conductors 41 and in the regions around the linear conductors 41 if the length of the linear conductors 41 and the grooves 42 is insufficient because of the limited mounting space on the printed wiring board 1C. Thus, even under conditions where the solder 52A and the flux 52B are not easily spread in the plane of the printed wiring board 1C, the molten solder 52A and flux 52B may flow into the recesses 44A to 44D to well reduce the amount of solder 52A and flux 52B wetting up.

Although the example illustrated in FIG. 23 has the recesses 44A to 44D formed only in the surfaces of the linear conductors 41 and around the linear conductors 41 in the linear conductor group 40A, the recesses 44A to 44D may also be formed in the other linear conductor groups 40B to 40D. In addition, the printed wiring boards according to the other examples may have the recesses 44A to 44D formed in the surfaces of the linear conductors 41 and around the linear conductors 41.

Although the above embodiments illustrate the case where a soldering portion on which an IMD such as the connector 2 is mounted controls the amount of solder and flux wetting up, other cases are contemplated. For example, a general-purpose soldering portion on which an SMD such as the chip component 3 is mounted may control the amount of solder and flux wetting up during reflow treatment. In this case, a plurality of linear conductors 41 may be disposed around the pads 14 so as to extend linearly from the pads 14. This inhibits excessive wetting-up of the solder and flux contained in the solder paste supplied to the pads 14 during reflow treatment. The above embodiments may be practiced in any possible combination.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A printed wiring board comprising:
a substrate; and
a soldering portion disposed on the substrate, an electronic component being to be soldered to the solder portion, the soldering portion including,
a first conductor, a solder paste being applied to the first conductor, and
a plurality of second conductors extending in a direction away from the first conductor, the plurality of second conductors extending parallel to each other and linearly.

2. The printed wiring board according to claim 1,
wherein a channel is formed by a pair of the second conductors parallel and adjacent to each other and a surface of the substrate between the pair of the second conductors.

3. The printed wiring board according to claim 1,
wherein the soldering portion is formed by a portion of a conductive layer disposed on the substrate, the portion of the conductive layer being exposed in an opening of a solder resist covering the conductive layer, and
wherein the channel is formed by one of the second conductors and surfaces of the solder resist on both sides of the second conductor.

4. The printed wiring board according to claim 1,
wherein the printed wiring board has a hole that is open upward in a surface thereof, the hole being formed in surfaces of the second conductors, around the second conductors, or both.

5. The printed wiring board according to claim 1,
wherein the substrate has a through-hole extending through the substrate across the thickness thereof, and
wherein the first conductor surrounds the through-hole.

6. A soldering method for mounting an electronic component on a printed wiring board, the soldering method comprising:
supplying a solder paste to a first conductor, the first conductor being included in a solder portion that includes a plurality of second conductors, the solder portion being formed on the printed wiring board, the plurality of second conductors extending in a direction away from the first conductor, the plurality of second conductors extending parallel to each other and linearly, the electric component being connected to the soldering portion; and
performing reflow heating with the electronic component mounted on the printed wiring board,
wherein a portion of the molten solder paste flows from the first conductor to the second conductors in the reflow heating.

7. The soldering method according to claim 6,
wherein a channel is formed by a pair of the second conductors parallel and adjacent to each other and a surface of the substrate between the pair of the second conductors.

8. The soldering method according to claim 6,
wherein the soldering portion is formed by a portion of a conductive layer disposed on the substrate, the portion of the conductive layer being exposed in an opening of a solder resist covering the conductive layer, and
wherein the channel is formed by one of the second conductors and surfaces of the solder resist on both sides of the second conductor.

9. The soldering method according to claim 6,
wherein the printed wiring board includes a hole that is open upward in a surface thereof, the hole being formed in surfaces of the second conductors, around the second conductors, or both.

10. The soldering method according to claim 6,
wherein the substrate has a through-hole extending through the substrate across the thickness thereof, and
wherein the first conductor surrounds the through-hole.
